(19) United States
(12) Patent Application Publication
(10) Pub. No.: US 2011/0284895 A1
(43) Pub. Date: Nov. 24, 2011

(54) LIGHT-EMITTING SEMICONDUCTOR DEVICE

(75) Inventor: Sheng-Hsien Hsu, Taiping City (TW)

(73) Assignee: HUGA OPTOTECH INC., Taichung (TW)

(21) Appl. No.: 13/084,782

(22) Filed: Apr. 12, 2011

(30) Foreign Application Priority Data
May 24, 2010 (TW) 99116489

(51) Int. Cl. H01L 33/58

(52) U.S. Cl. 257/98; 257/E33.074

(57) ABSTRACT

The present invention provides a light-emitting semiconductor device, which comprises a substrate having a surface formed with a plane and a plurality of protrusions out of the plane. The plane is on a crystalline orientation. The protrusion is provided with an outer surface consisting of a plurality of sidewall surfaces. The sidewall surfaces are substantially not on the crystalline orientation. The protrusion is formed with an outline edge extended from the bottom to the top of the protrusion from a side view. The outline edge comprises at least one turning point. A first conductive type semiconductor layer is above the surface of the substrate, an active layer is above the first conductive type semiconductor layer, and a second conductive type semiconductor layer is above the active layer.

### CROSS REFERENCE TO RELATED APPLICATIONS

This application claims the right of priority based on Taiwan Patent Application No. 099116489 entitled “LIGHT-EMITTING SEMICONDUCTOR DEVICE,” filed on May 24, 2010, which is incorporated herein by reference and assigned to the assignee herein.

### FIELD OF INVENTION

The present invention relates to light-emitting semiconductor devices, and more particularly, to a light-emitting semiconductor device having improved epitaxial quality and enhanced light extraction efficiency.

### BACKGROUND OF THE INVENTION

The light emitting diode is a kind of various light-emitting semiconductor devices, which is advantageous with small volume, longevity, low voltage/current requirements, less fragile, less heat issues during emission, mercury-free, and low power consumption, and thus being extensively and widely used in many applications.

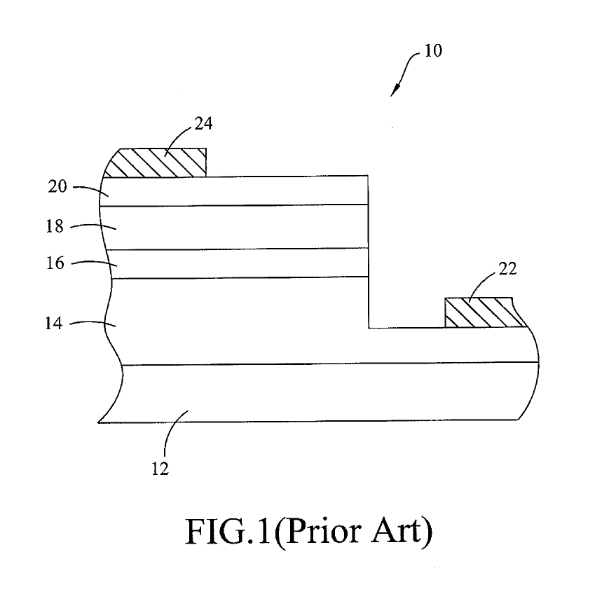

FIG. 1 is a cross section of a conventional light emitting diode 10. Referring to FIG. 1, a light emitting diode 10 includes a substrate 12, a first conductive type semiconductor layer 14, an active layer 16, a second conductive type semiconductor layer 18, an ohmic contact layer 20, a first electrode 22 and a second electrode 24, wherein the first conductive type semiconductor layer 14, the active layer 16, and the second conductive type semiconductor layer 18 can be, for example, epitaxial layers.

When the light emitting diode 10 is exemplified as a blue light emitting diode, the substrate can be a sapphire (Al₂O₃) and the gallium nitride (GaN) epitaxial layer can be directly formed on the substrate. However, the lattice constant difference between the sapphire substrate 12 and the gallium nitride epitaxial layer is large, which generates defects in the epitaxial layer, therefore affecting emitting efficiency of the light emitting diode 10. Accordingly, the published prior art, such as US Patent Pub. No. 20080303042, the entity of which is hereby incorporated by reference, discloses a substrate with patterned recess/protrusion structures to improve emitting efficiency of the light emitting diode. However, defects are still existed in the light emitting diode using aforementioned techniques.

### SUMMARY OF THE INVENTION

One aspect of the present invention provides a light-emitting semiconductor device with improved epitaxial quality.

Another aspect of the present invention provides a light-emitting semiconductor device with enhanced light extraction efficiency

According to an embodiment of the invention, a light-emitting semiconductor device comprises a substrate having a surface formed with a plane and a plurality of protrusions out of the plane. The plane is on a crystalline orientation. The protrusion is provided with an outer surface consisting of a plurality of sidewall surfaces. The sidewall surfaces are substantially not on the crystalline orientation. The protrusion is formed with an outline edge extended from the bottom to the top of the protrusion from a side view. The outline edge comprises at least one turning point. A first conductive type semiconductor layer is above the surface of the substrate, an active layer is above the first conductive type semiconductor layer, and a second conductive type semiconductor layer is above the active layer.

According to another embodiment of the invention, a light-emitting semiconductor device comprises a substrate having a surface formed with a plane and a plurality of protrusions out of the plane, wherein the plane is C-plane (0001). The protrusion is provided with an outer surface consisting of a plurality of sidewall surfaces, which are substantially not the C-plane. The protrusion is formed with an outline edge extended from the bottom to the top of the protrusion from a side view. The outline edge comprises at least one turning point. A first conductive type semiconductor layer is above the surface of the substrate, an active layer is above the first conductive type semiconductor layer, and a second conductive type semiconductor layer is above the active layer.

### BRIEF DESCRIPTION OF THE PICTURES

The foregoing aspects and many of the attendant advantages of this invention will become more readily appreciated as the same becomes better understood by reference to the following detailed description, when taken in conjunction with the accompanying pictures, wherein:

FIG. 1 is a schematic cross section of a conventional light emitting diode;

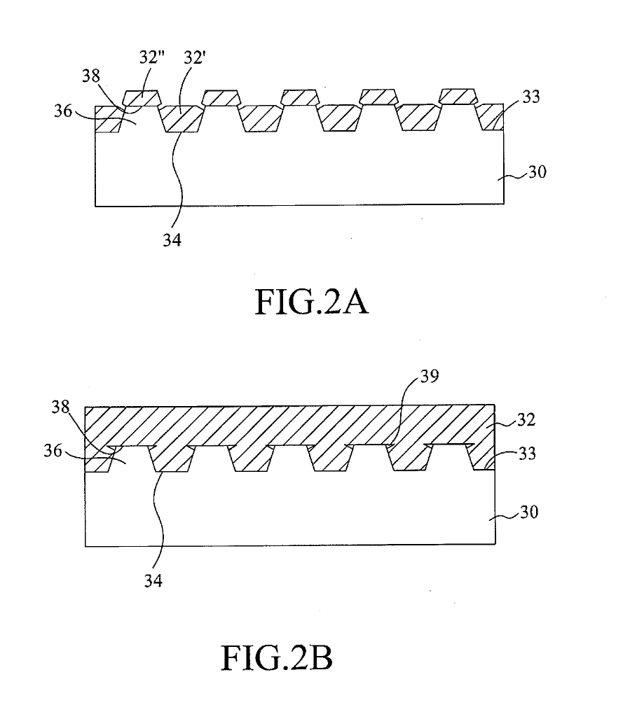

FIG. 2A and FIG. 2B are schematic cross section views illustrating formation of forming an epitaxial layer using a patterned substrate;

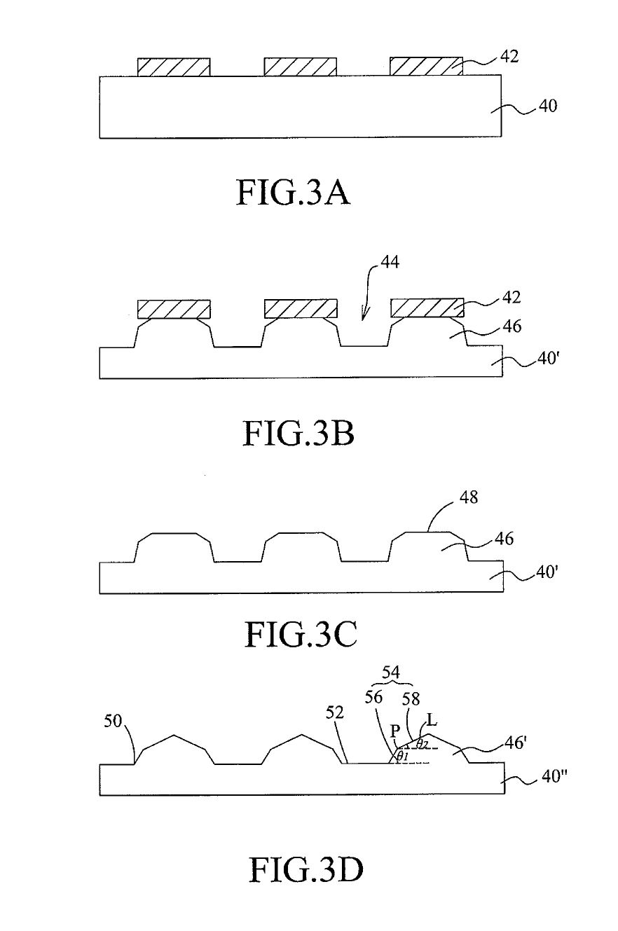

FIGS. 3A to 3D are a series of schematic cross sections illustrating formation of a patterned substrate in accordance with an embodiment of the invention;

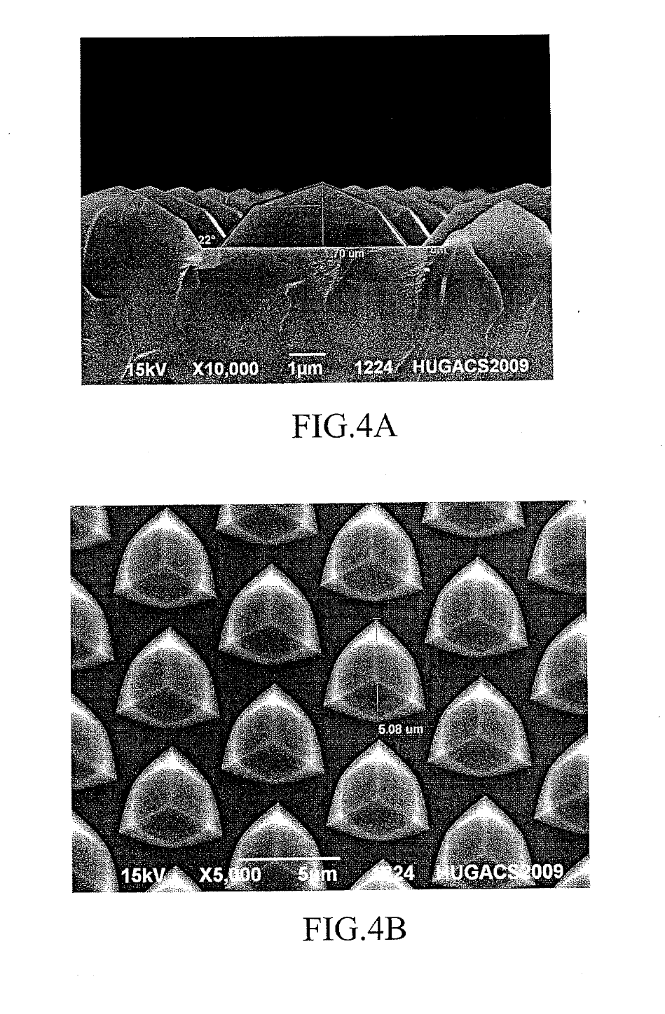

FIG. 4A and FIG. 4B show a side view and a plan view of the patterned sapphire substrate in accordance with an embodiment of the invention;

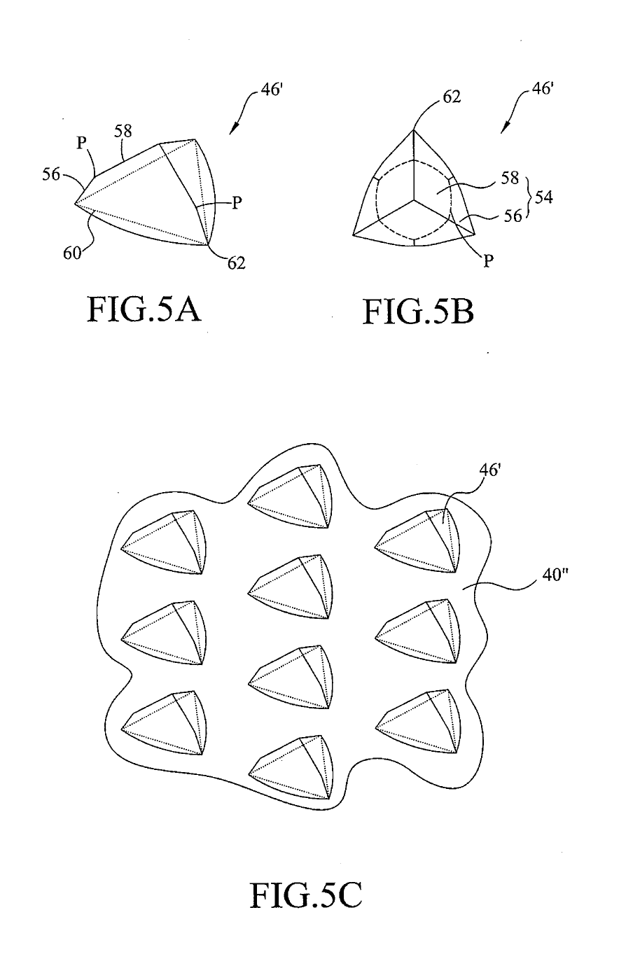

FIG. 5A and FIG. 5B respectively show perspective view and plan view of a protrusion in accordance with an embodiment of the invention; FIG. 5C schematically shows a perspective view of a substrate for formation of the light-emitting semiconductor devices in accordance with an embodiment of the invention; and

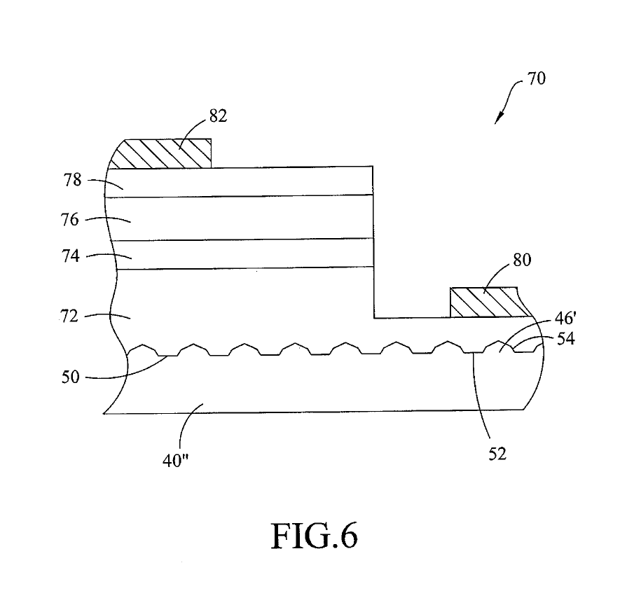

FIG. 6 is a cross section illustrating a light-emitting semiconductor device 70 based on the substrate 40″ in accordance with an embodiment of the invention.

### DETAILED DESCRIPTION OF THE INVENTION

Reference will now be made in detail to the present preferred embodiments of the invention, examples of which are illustrated in the accompanying drawings. Wherever possible, the same reference numbers are used in the drawings and the description to refer to the same or like parts. In the drawings, the shape and thickness of an embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be presented.

The preferred embodiments of the present invention will now be described in greater details by referring to the drawings that accompany the present application. It should be noted that the features illustrated in the drawings are not necessarily drawn to scale. Descriptions of well-known components, materials, and process techniques are omitted so as to not unnecessarily obscure the embodiments of the invention. Any devices, components, materials, and steps described in the embodiments are only for illustration and not intended to limit the scope of the present invention.

FIG. 2A and FIG. 2B are schematic cross section views of forming an epitaxial layer 32 using a patterned substrate 30. Referring to FIG. 2A, the patterned substrate 30 includes a surface 33 for formation of the epitaxial layer 32. The surface 33 comprises a bottom plane 34 and protrusions 36 out of the bottom plane 34, wherein the protrusions 36 includes a top plane 38 being paralleled to the bottom plane 34. Since both the bottom plane 34 of the substrate 33 and the top plane 38 of the protrusions 36 have a crystalline orientation suitable for growth of the epitaxial layer 32 as shown in FIG. 2A, the epitaxial layers 32′ and 32″ are respectively and simultaneously formed from the bottom plane 34 and the top plane 38. When the epitaxial layers 32′ and 32″ are simultaneously laterally grown on the bottom plane 34 and the top plane 38, however, the vacancy defects 32 (as shown in FIG. 2B) can be easily formed above the protrusions 36 in the resulting epitaxial layer 32, thus further affecting emission efficiency of the subsequently formed light-emitting semiconductor device.

In view of the aforementioned problems, the following embodiments provide a light-emitting semiconductor device having a patterned substrate capable of improving epitaxial quality and enhancing light extraction efficiency.

FIGS. 3A to 3D are a series of schematic cross sections illustrating formation of a patterned substrate in accordance with an embodiment of the invention. The patterned substrate can be used for forming a light-emitting semiconductor device in the subsequent fabrication process. Referring to FIG. 3A, a substrate is provided. Materials and characteristics of the substrate 40 can be determined in accordance with the type of the desirably formed light-emitting semiconductor device and the materials of the subsequently formed epitaxial layer on the substrate 40. A blue light emitting diode is exemplified in the present embodiment in which a sapphire substrate is used as the substrate 40.

Next, a patterned passivation layer 42 is formed on the substrate 40. In the present embodiment, formation of the patterned passivation layer 42 includes forming a silicon oxide layer by using any thin-film deposition technique well known in the art, and then forming circle patterns with suitable diameters using lithography and etching techniques. The patterned passivation layer 42 can be formed according to practical requirements, but not limited thereto, with suitable shapes, dimensions, and arrangements on the substrate 40.

Referring to FIG. 3B, a first etching step is performed to from a substrate 40′ with recesses 44. Protrusions 46 with two tapered planes are created at the locations of the substrate 40′ masked by the patterned passivation layer 42. In the present embodiment, wet etching is preferably used in the first etching step. The substrate 40 is immersed in an etchant which is a solution preferably exhibiting an excellent etching selective ratio between the substrate 40 and the patterned passivation layer 42. In this embodiment, the substrate 40 can be a sapphire substrate with C-plane (0001). The patterned passivation layer 42 can be silicon oxide. The etchant can be, but is not limited to, a solution comprising sulfuric acid, phosphoric acid, or combinations thereof.

Next, the patterned passivation layer 42 is removed from the substrate 40′; meanwhile, top portion of the protrusions 46 on the substrate 40′ has a top plane 48 protected by the patterned passivation layer 42, as shown in FIG. 3C.

After the patterned passivation layer 42 is removed, a second etching step is performed on the substrate 40′ to sharpen the top plane 48 of the protrusions 46, thereby forming a substrate 40″ for subsequent formation of the epitaxial layers, as shown in FIG. 3D. The substrate 40″ has a surface 50 which includes a plane 52 with a crystalline orientation suitable for epitaxial growth and a plurality of protrusions 46′ of the top planes non-parallel to the plane 52. In the present embodiment, the second etching step can also be a wet etching in which the etchant can be the same as that used in the first etching step.

Each of the protrusions 46′ of the present embodiment has outer surfaces consisting essentially of a plurality of sidewall surfaces 54, three for example. These sidewall surfaces 54 are non-parallel to the plane 52 of the substrate 40″. Specifically, the crystalline orientation of the sidewall surfaces 54 are substantially excluded from the crystalline orientation of the plane 52, i.e., the C-plane (0001), thus subsequently forming better quality of epitaxial layers. Referring to FIG. 3D, the protrusion 46′ has an outer profile L from a side-view. The outer profile L includes at lest one turning point from the bottom to the top of the protrusions 46′. Referring to FIG. 3D, from a side view, each of the sidewall surfaces 54 of the protrusions 46′ consists essentially of a lower sidewall surface 56 and a upper sidewall surface 58, wherein the lower sidewall surface 56 is interposed between the plane 52 and the upper sidewall surface 58. The lower sidewall surface 56 connects the plane 52 to the upper sidewall surface 58, wherein a first inclined angle θ1 is included between the lower sidewall surface 56 and the plane 52, a second inclined angle θ2 is included between the upper sidewall surface 58 and the plane 52, and the first inclined angle θ1 is different from the second inclined angle θ2. In this embodiment, the first inclined angle θ1 exceeds the second inclined angle θ2. Inclination of the sidewall surfaces 54 of the protrusions 46′ can be controlled by adjusting etching process parameters.

In the present embodiment, since the protrusion 46′ of the substrate 40″ excludes the top plane parallel to the plane 52, i.e., the protrusion 46′ does not include a top plane with C-plane (0001) on which is suitable for epitaxial growth, defects such as vacancies can be prohibitively formed in the epitaxial layers subsequently formed on the surface 50 of the substrate 40″, thus exhibiting better epitaxial quality.

FIG. 4A and FIG. 4B are images taken with a scanning electron microscope (SEM) respectively illustrating plan view and side view of the patterned sapphire substrate in accordance with an embodiment of the invention.

FIG. 5A and FIG. 5B respectively show perspective view and plan view of a protrusion 46′ in accordance with an embodiment of the invention. FIG. 5C schematically shows a perspective view of a substrate 40″ for formation of the light-emitting semiconductor device in accordance with an embodiment of the invention.

The protrusion 46′ includes a quasi-polygonal bottom plane 60. In the present embodiment, referring to FIGS. 5A and 5B, the quasi-polygonal bottom plane 60 of the protrusion 46′ includes three corners 62, and the bottom plane 60 between the corners 62 are arched.

The sidewall surfaces 54 can substantially be a curved surface, a plane or combinations thereof. When the protrusion 46′ is taken from a side-view, the connection between the lower sidewall surface 56 and the upper sidewall surface 58 is indicated as an turning point P, wherein the turning point P is substantially located at the intersection of the connection between the sidewall surfaces 54 and the connection between the lower sidewall surface 56 and the upper sidewall surface 58 with different inclinations or different curvatures.

Referring to FIG. 5C, the protrusions 46′ on the substrate 40″ are separated from one another and have a regular and staggered arrangement. Separation distance and arrangement of the protrusions 46′ can be determined by practical requirements, but not limited thereto. Preferably, the height of the protrusions 46′ is approximately in a range of 2 μm to 5 μm, and the width of the protrusions 46′ is approximately in a range of 3 μm to 7 μm.

FIG. 6 is a cross section illustrating a light-emitting semiconductor device 70 based on the substrate 40″ in accordance with an embodiment of the invention. Referring to FIG. 6, the light-emitting semiconductor device 70 includes a first conductive type semiconductor layer 72 on the surface 50 of the substrate 40″, an active layer 74 on the first conductive type semiconductor layer 72, and a second conductive type semiconductor layer 76 on the active layer 74. In the present embodiment, the first conductive type semiconductor layer can be an N-type semiconductor layer, and the second conductive type semiconductor layer can be a P-type semiconductor layer. All of the first conductive type semiconductor layer 72, the active layer 74 and the second conductive type semiconductor layer 76 can be an epitaxial layer. A first electrode 80 and a second electrode 82 can be respectively disposed on the first conductive type semiconductor layer 72 and the second conductive type semiconductor layer 76. In this embodiment, an ohmic contact layer 78 is interposed between the second conductive type semiconductor layer 76 and the second electrode 82.

According to the present embodiment, the first conductive type semiconductor layer 72 can be epitaxially grown on the surface 50 of the substrate 40″. Since there are pluralities of protrusions 46′ on the surface 50 of the substrate 40″, dislocations in the epitaxial layer can thus be reduced. Moreover, in the present embodiment, sidewall surfaces 54 of the protrusions 46′ on the substrate 40″ include a crystalline orientation substantially unsuitable for growth of the epitaxial layer, thereby reducing defects generated in the epitaxial layer and improving epitaxial quality and light extraction efficiency. In this regard, the light-emitting semiconductor device 70 of the present embodiment exhibits better production yield, and more excellent quantum emitting efficiency.

Furthermore, in the present embodiment, since from the bottom to the top of the lateral side of the protrusions 46′ on the substrate 40″ there are one or more turning points, light beams can be more efficiently reflected, thereby improving light extraction efficiency.

The substrate 40″ can, however, include protrusions 46′ with various shaped in accordance with materials of the substrate 40, shapes and dimensions of the patterned passivation layer 24 and etching methods and processing parameters. For example, the polygonal bottom plane of the protrusion 46′ can include other various polygonal shapes. The turning points on the lateral side of the protrusion 46′ can be more than one. For example, the upper sidewall surface 58 of the protrusion 46′ can include a first upper sidewall surface and a second upper sidewall surface, wherein the first upper sidewall surface is interposed between the lower sidewall surface and the second upper sidewall surface and connects the lower sidewall surface and the second upper sidewall surface. When the protrusion is taken from a side-view, the connection between the first upper sidewall surface and the second upper sidewall surface can also be a turning point.

While the invention has been described by way of examples and in terms of preferred embodiments, it would be apparent to those skilled in the art to make various equivalent replacements, amendments and modifications in view of specification of the invention. Therefore, the scope of the appended claims should be accorded the broadest interpretation so as to encompass all such replacements, amendments and modifications without departing from the spirit and scope of the invention.

1. A light-emitting semiconductor device, comprising:
a substrate having a surface formed with a plane and a plurality of protrusions out of the plane, wherein the plane is on a crystalline orientation, a protrusion of the plurality of protrusions is provided with an outer surface consisting of a plurality of sidewall surfaces which are substantially not on the crystalline orientation, the protrusion is formed with an outline edge extended from the bottom to the top of the protrusion from a side view, and the outline edge comprises at least one turning point;
a first conductive type semiconductor layer above the surface of the substrate;
an active layer above the first conductive type semiconductor layer; and
a second conductive type semiconductor layer above the active layer.

2. The light-emitting semiconductor device as claimed in claim 1, wherein each of the sidewall surfaces includes a lower sidewall surface and an upper sidewall surface, the lower sidewall surface connects the plane and the upper sidewall surface, and when the protrusion is taken from a side view, the connection between the lower sidewall surface and the upper sidewall surface is the turning point.

3. The light-emitting semiconductor device as claimed in claim 2, wherein a first inclined angle is set between the lower sidewall surface and the plane and a second inclined angle is set between the upper sidewall surface and the plane, wherein the first inclined angle is different from the second inclined angle.

4. The light-emitting semiconductor device as claimed in claim 3, wherein the first inclined angle exceeds the second inclined angle.

5. The light-emitting semiconductor device as claimed in claim 2, wherein the number of the sidewall surfaces of the protrusion is three, and the sidewall surface consists essentially of the lower sidewall surface and the upper sidewall surface.

6. The light-emitting semiconductor device as claimed in claim 2, wherein the upper sidewall surface includes a first upper sidewall surface and a second upper sidewall surface, the first upper sidewall surface connects the lower sidewall surface and the second upper sidewall surface, and when the protrusion is taken from a side-view, the connection between the first upper sidewall surface and the a second upper sidewall surface is the turning point.

7. The light-emitting semiconductor device as claimed in claim 1, wherein the sidewall surface includes a curved surface, a plane or combinations thereof.

8. The light-emitting semiconductor device as claimed in claim 1, wherein the protrusion includes a quasi-polygonal bottom plane.

9. The light-emitting semiconductor device as claimed in claim 8, wherein the bottom plane includes three corners.

10. The light-emitting semiconductor device as claimed in claim 9, wherein edges of the bottom plane between the corners are arched.

11. The light-emitting semiconductor device as claimed in claim 1, wherein the protrusions are separated from one another and have a regular and staggered arrangement.

12. A light-emitting semiconductor device, comprising:
a substrate having a surface formed with a plane and a plurality of protrusions out of the plane, wherein the plane is C-plane (0001), a protrusion of the plurality of protrusions is provided with an outer surface consisting of a plurality of sidewall surfaces which are substantially not the C-plane, the protrusion is formed with an outline edge extended from the bottom to the top of the protrusion from a side view, and the outline edge comprises at least one turning point;
a first conductive type semiconductor layer above the surface of the substrate;
an active layer above the first conductive type semiconductor layer; and
a second conductive type semiconductor layer above the active layer.
